(19) United States
(12) Patent Application Publication
(10) Pub. No.: US 2017/0102405 A1
(43) Pub. Date: Apr. 13, 2017

(54) MONITORING SYSTEM AND METHOD FOR ELECTRONIC DEVICE

(71) Applicant: HON HAI PRECISION INDUSTRY CO., LTD., New Taipei (TW)

(72) Inventor: YU-CHEN HUANG, New Taipei (TW)

(21) Appl. No.: 14/921,151

(22) Filed: Oct. 23, 2015

(30) Foreign Application Priority Data
Oct. 9, 2015 (CN) 201510647893.3

(51) Int. Cl. G01P 3/00; G01R 19/00; H02P 31/00; G01K 1/14

(52) U.S. Cl. CPC G01P 3/00; G01K 1/14; G01R 19/0084; H02P 31/00

(57) ABSTRACT

A monitoring system for monitoring running state of an electronic device includes a fan, a Pulse-Width Modulation (PWM) register, a Baseboard Management Controller (BMC), a temperature sensor, and a Basic Input Output System (BIOS) chipset. The PWM register is coupled to the fan and stores a pulse width value of a driven voltage which drives the fan to rotate. The Baseboard Management Controller (BMC) is coupled to the PWM register. The temperature sensor is coupled to the BMC and senses an inner temperature of an electronic device. The BIOS chipset is coupled to the BMC and adjusts the pulse width value of the driven voltage based on the inner temperature sensed by the temperature sensor to vary a rotation speed of the fan.

### CROSS-REFERENCE TO RELATED APPLICATIONS

This application claims priority to Chinese Patent Application No. 201510647893.3 filed on Oct. 9, 2015, the contents of which are incorporated by reference herein.

### FIELD

The subject matter herein generally relates to monitoring systems and methods, and more particularly to a monitoring system and method for monitoring running state of an electronic device.

### BACKGROUND

Electronic devices, such as servers, can be monitored while the electronic devices are running For example, the electronic devices can also have variety of different states that are monitored; the states can include items such as input voltage and inner temperature.

### BRIEF DESCRIPTION OF THE DRAWINGS

Implementations of the present technology will now be described, by way of example only, with reference to the attached figures.

FIG. 1 is a block view of one monitoring system for electronic device.

FIG. 2 is a flow chart of one monitoring method for electronic device.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series and the like.

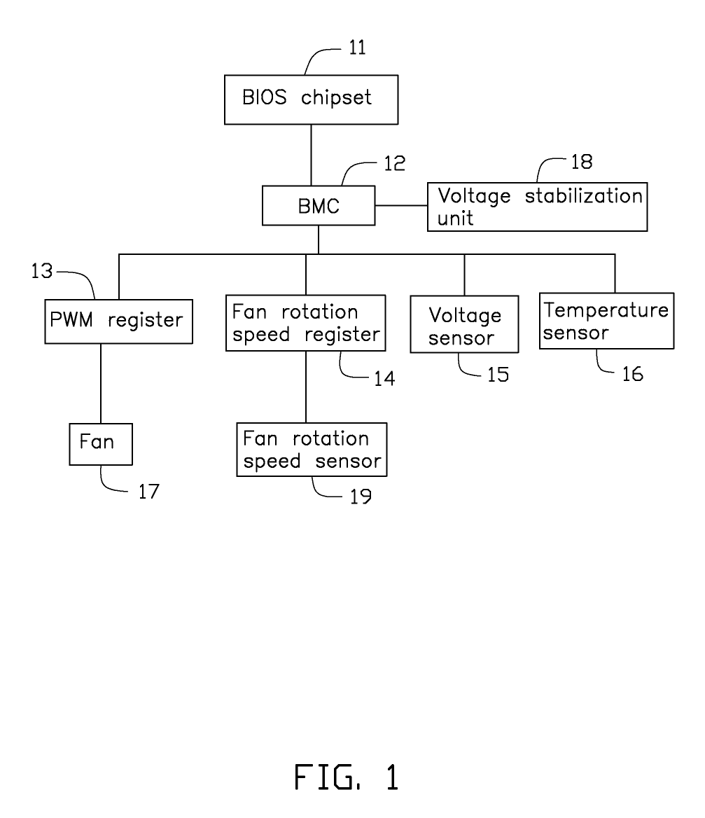

FIG. 1 illustrates a monitoring system for monitoring running state of an electronic device in accordance with an embodiment. The monitoring system includes a Basic Input Output System (BIOS) chipset 11, a Baseboard Management Controller (BMC) 12, a Pulse-Width Modulation (PWM) register 13, a fan rotation speed register 14, a voltage sensor 15, a temperature sensor 16, a fan 17, a voltage stabilization unit 18, and a fan rotation speed sensor 19.

The BIOS chipset 11 is coupled to the BMC 12. The PWM register 13, the fan rotation speed register 14, the voltage sensor 15, the temperature sensor 16, and the voltage stabilization unit 18 are coupled to the BMC 12. The PWM register 13 is coupled to the fan. The fan rotation speed register 14 is coupled to the fan rotation speed sensor 19.

The BIOS chipset 11 detects a working state of the BMC 12. The BIOS chipset 11 periodically sends a detection signal to the BMC 12. When the BMC 12 works normally, the BMC sends a responding signal back to the BIOS chipset 11 after the BMC 12 receives the detection signal. When the BMC 12 works abnormally, the BMC 12 cannot send a responding signal back to the BIOS chipset 11. When the BIOS chipset 11 detects that the BMC 12 works abnormally, the BIOS chipset 11 is directly coupled to the PWM register 13, the fan rotation speed register 14, the voltage sensor 15, the temperature sensor 16, and the voltage stabilization unit 18.

The PWM register 13 stores a pulse width value of a driven voltage which drives the fan 17 to rotate. When the pulse width value of the driven voltage is changed, a rotation speed of the fan 17 varies.

The fan rotation speed sensor 19 is used to sense a rotation speed of the fan 17, and stores the rotation speed of the fan 17 in the fan rotation speed register 14.

The voltage sensor 15 senses an input voltage of the electronic device.

The temperature sensor 16 senses an inner temperature of the electronic device, and sends the inner temperature of the electronic device to the BMC 12. The rotation speed of the fan 17 is controlled based on the inner temperature of the electronic device.

The voltage stabilization unit 18 is used to stabilize the input voltage of the electronic device when the voltage sensor 15 senses that the input voltage is unstable.

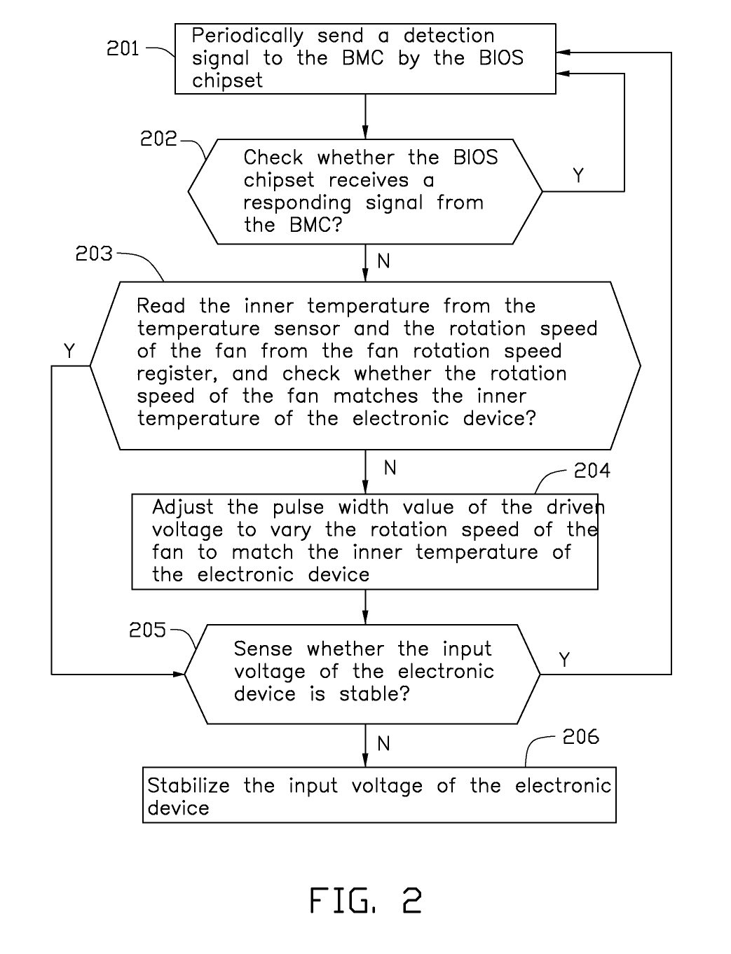

FIG. 2 illustrates a flow chart of a method for monitoring running state of the electronic device includes following steps.

At block 201, the method includes periodically sending a detection signal to the BMC 12 by the BIOS chipset 11.

At block 202, the method includes checking whether the BIOS chipset 11 receives a responding signal from the BMC. If not, go to step 203. If yes, go back to step 201.

At block 203, the method includes reading the inner temperature from the temperature sensor 16 and the rotation speed of the fan 17 from the fan rotation speed register 14 by the BIOS chipset 11, and checking whether the rotation speed of the fan 17 matches the inner temperature of the electronic device by the BIOS chipset 11. If yes, go to step 205. If not, go to step 204.

At block 204, the method includes adjusting the pulse width value of the driven voltage to vary the rotation speed of the fan 17 to match the inner temperature of the electronic device.

At block 205, the method includes sensing whether the input voltage of the electronic device is stable by the voltage sensor 15. If yes, go to step 201. If not, go to step 206.

At block 206, the method includes stabilizing the input voltage of the electronic device by the voltage stabilization unit 18.

The embodiments shown and described above are only examples. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to, and including, the full extent established by the broad general meaning of the terms used in the claims. It will therefore be appreciated that the embodiments described above may be modified within the scope of the claims.

What is claimed is:

1. A monitoring system for monitoring running state of an electronic device, the monitoring system comprising:
a fan;
a Pulse-Width Modulation (PWM) register coupled to the fan, the PWM register storing a pulse width value of a driven voltage which drives the fan to rotate;
a Baseboard Management Controller (BMC) coupled to the PWM register;
a temperature sensor coupled to the BMC and configured to sense an inner temperature of an electronic device; and
a Basic Input Output System (BIOS) chipset coupled to the BMCand configured to adjust the pulse width value of the driven voltage based on the inner temperature sensed by the temperature sensor to vary a rotation speed of the fan.

2. The monitoring system of claim 1, wherein the BIOS chipset varies the rotation speed of the fan to match the inner temperature.

3. The monitoring system of claim 1, wherein the BIOS chipset detects a working state of the BMC.

4. The monitoring system of claim 1, wherein the BIOS chipset periodically sends a detection signal to the BMC, the BMC sends a responding signal back to the BIOS chipset when the BMC works normally, and the BMC does not send a responding signal back to the BIOS chipset when the BMC works abnormally.

5. The monitoring system of claim 1, further comprising a voltage sensor, wherein the voltage sensor senses whether an input voltage of an electronic device is stable.

6. The monitoring system of claim 5, further comprising a voltage stabilization unit, wherein the voltage stabilization unit stables the input voltage when the sensor senses that the input voltage is unstable.

7. A monitoring method for monitoring running state of an electronic device, the monitoring method comprising:
periodically checking whether a BMC works normally by a BIOS chipset;
the BIOS chipset reading an inner temperature of an electronic device sensed by a temperature sensor and a rotation speed of a fan sensed by a fan rotation speed sensor when the BMC works abnormally;
the BIOS chipset checking whether the rotation speed of the fan matches the inner temperature; and
adjusting the pulse width value of the driven voltage to vary the rotation speed of the fan to match the inner temperature of the electronic device when the rotation speed of the fan does not match the inner temperature.

8. The monitoring method of claim 7, further comprising a voltage sensor sensing whether an input voltage of the electronic device is stable.

9. The monitoring method of claim 8, further comprising a voltage stabilization unit stabilizing the input voltage of the electronic device when the voltage sensor senses that an input voltage of the electronic device is unstable.

10. The monitoring method of claim 7, wherein the BIOS chipset periodically sends a detection signal to the BMC to check whether a BMC works normally.

11. The monitoring method of claim 10, wherein the BMC sends a responding signal back to the BIOS chipset when the BMC works normally, and the BMC does not send a responding signal back to the BIOS chipset when the BMC works abnormally.

12. The monitoring method of claim 7, wherein the temperature sensor and the fan rotation speed sensor are coupled to the BMC.
